(19) United States
(12) Patent Application Publication
(10) Pub. No.: US 2023/0282567 A1
(43) Pub. Date: Sep. 7, 2023

(54) Power Semiconductor Module with Two Opposite Half-Bridges

(71) Applicant: ZF Friedrichshafen AG, Friedrichshafen (DE)

(72) Inventor: Wei Liu, Friedrichshafen (DE)

(21) Appl. No.: 18/177,933

(22) Filed: Mar. 3, 2023

(30) Foreign Application Priority Data
Mar. 4, 2022 (DE) 10 2022 202 252.1

(51) Int. Cl. H01L 23/52; H01L 25/16; H01L 23/367; H02M 7/00

(52) U.S. Cl. CPC H01L 23/52; H01L 25/16; H01L 23/3675; H02M 7/003

(57) ABSTRACT

A power semiconductor module (10) includes a multilayer circuit board (18) with a first outer conducting layer (20a), a first isolating layer (22a), an intermediate conducting layer (24), a second isolation layer (22b), and a second outer conducting layer (20b). A first semiconductor chip (T1) and a second semiconductor chip (T2) are bonded to the first outer conducting layer (20a), and a third semiconductor chip (T3) and a fourth semiconductor chip (T4) are bonded to the second outer conducting layer (20b). A DC− area (30) of the first outer conducting layer (20a) and a DC− area (30) of the second outer conducting layer (20b) are connected to the intermediate conducting layer (24). A DC+ terminal (DC+) is connected to a DC+ area (26) of the first outer conducting layer (20a) and to a DC+ area (26) of the second outer conducting layer (20b).

### CROSS-REFERENCE TO RELATED APPLICATIONS

The present application is related and claims priority to 102022202252.1 filed in the German Patent Office on Mar. 4, 2022, which is incorporated by reference in its entirety for all purposes.

### FIELD OF THE INVENTION

The invention relates to a power semiconductor module.

### BACKGROUND

In automotive applications with electrical drives, such as electrical cars and trucks, half-bridge modules are used for assembling inverters, which generate the AC current, which is needed for driving an electrical motor, from a DC current, which may be provided by an electrical battery. Currently, such half-bridge modules comprise Si semiconductors. However, due to the higher operation voltages and the possible higher switching frequencies of Si semiconductors, which may result in lower losses and a more efficient application of the half-bridge modules, it is also considered to use high bandgap semiconductors.

Such power semiconductor modules based on high bandgap semiconductors may benefit from new module designs, since higher switching frequencies usually result in different and/or higher electromagnetic radiation and losses. Also, an operation at higher voltages may need better local cooling capabilities.

### SUMMARY OF THE INVENTION

Example aspects of the present invention provide a power semiconductor module, which reduces the above-mentioned problems.

A first example aspect of the invention relates to a power semiconductor module. A power semiconductor module is a device for mechanically and electrically interconnecting power semiconductor chips. Here and in the following, the term “power” refers to devices and elements adapted for processing voltages of more than one hundred volts (100 V) and/or more than ten amps (10 A).

According to an example embodiment of the invention, the power semiconductor module includes a multilayer circuit board with a first outer conducting layer, a first isolating layer, an intermediate conducting layer, a second isolation layer and a second outer conducting layer, which are arranged in this order. The first isolation layer is sandwiched between the first outer conducting layer and the intermediate conducting layer. The second isolation layer is sandwiched between the second outer conducting layer and the intermediate conducting layer. The conducting layers may be made of metal, such as copper and/or may be metallization layers. The isolating layers may be made of plastics and/or ceramics.

According to an example embodiment of the invention, the power semiconductor module includes a first semiconductor chip and a second semiconductor chip, which are bonded to the first outer conducting layer and a third semiconductor chip and a fourth semiconductor chip, which are bonded to the second outer conducting layer. Such semiconductor chips may have a plastics housing, which encloses a die made of a semiconductor material, which provides the functionality of the chip. The semiconductor chips may include controllable switches, such as transistors and/or thyristors. In particular, the semiconductor chips may include HEMTs. Every semiconductor chip may provide two power electrodes to be supplied with the main current through the device (such as drain and source electrodes, or emitter and collector electrodes) and a control electrode for switching the main current (such as a gate electrode or a base electrode).

Here and in the following, bonding may refer to a process for electrically and mechanically connecting two metallic elements, such as soldering, welding, and sintering.

According to an example embodiment of the invention, the first outer conducting layer is structured into a DC+ area, an AC area, and a DC− area, which are separated from one another on the first isolating layer and which interconnect the first semiconductor chip and the second semiconductor chip into a half-bridge. Furthermore, the second outer conducting layer is structured into a DC+ area, an AC area, and a DC− area, which are separated from one another on the second isolating layer and which interconnect the third semiconductor chip and the fourth semiconductor chip into a half-bridge. The term “separated from each other on the electrically isolating layer” may mean that the corresponding components are electrically isolated from each other, when the respective switch chip is not present, i.e. bonded to the components. A half-bridge is a circuit, in which the corresponding two semiconductor chips, each of which includes a semiconductor switch, are series connected.

It also may be that the first outer conducting layer and/or the second outer conducting layer includes a control electrode area, which is separated from the other areas. Control electrodes of the semiconductor chips may be bonded to the control electrode areas. The power electrodes and, optionally, the control electrode of a semiconductor chip are provided on the same side of the semiconductor chip.

According to an example embodiment of the invention, the DC− area of the first outer conducting layer and the DC− area of the second outer conducting layer are connected to the intermediate conducting layer. A DC+ terminal is connected to the DC+ area of the first outer conducting layer and to the DC+ area of the second outer conducting layer. An AC terminal is connected to the AC area of the first outer conducting layer and to the AC area of the second outer conducting layer. A DC− terminal is connected to the intermediate conducting layer. The terminals may be parts of the power semiconductor module, where the power semiconductor module is electrically connected to further devices.

The terminals are connected such that the two half-bridges formed by the semiconductor chips are connected in parallel with respect to DC+, DC− and AC. Such half-bridges may be used for generating the phase of an AC current from a DC current. The power semiconductor module also may be seen as a half-bridge module.

Since the DC− areas are connected to the intermediate layer, which conducts the current through the DC− side of the power semiconductor module between the semiconductor chips and the electrical interconnection of the semiconductor chips, the power semiconductor module has a low inductance of the power conductor loop. This results in a lower stray inductance of power conductor loops formed by the power semiconductor module together with further electrical components to which the power semiconductor module is connected. This may be beneficial, when the power semiconductor chips are switched with higher frequencies as ordinary devices, which may be the case for chips based on a wide bandgap material.

Due to the half-bridges on each side of the multi-layer circuit board, the power semiconductor module provides a high power density. The arrangement of the components of the power semiconductor module results in a compact design. The usually substantially cuboid-shaped space occupied by the power semiconductor module may be designed to be more like a cube than a flat box. This may result in more freedom for assembling the semiconductor module into an inverter.

According to an example embodiment of the invention, the DC+ terminal and the DC− terminal are arranged at the same (small) side of the power semiconductor module. The layers of the multi-layer circuit board extend substantially parallel to a plane. Also, the sides of the multi-layer circuit board to which the semiconductor chips are bonded extend in this plane. The small sides of the multi-layer circuit board are located at a border of the multi-layer circuit board, which may have a substantially rectangular shape. The DC+ terminal and the DC− terminal may be arranged at the same small side. This may reduce the size of the power conductor loops.

According to an example embodiment of the invention, the DC− area of the first outer conducting layer and the DC− area of the second outer conducting layer are connected to the intermediate conducting layer at an opposite (small) side of the power semiconductor module opposite to the (small) side, where the DC+ terminal and the DC− terminal are arranged. In such a way, the current through the DC− terminal runs through the intermediate layer anti-parallel to the current through the first and second outer conducting layer.

According to an example embodiment of the invention, the AC terminal is arranged at a (small) side of the power semiconductor module, which runs orthogonal to the (small) side, where the DC+ terminal and the DC− terminal are arranged and/or to the (small) side, where the DC− areas are interconnected with the intermediate layer.

According to an example embodiment of the invention, the first semiconductor chip and the third semiconductor chip are arranged opposite to each other with respect to the multi-layer circuit board. Analogously, the second semiconductor chip and the fourth semiconductor chip are arranged opposite to each other with respect to the multi-layer circuit board. With respect to a view direction onto the plane of the multi-layer circuit board, the first (or second) semiconductor chip and the third (or fourth) semiconductor chip may overlap each other substantially completely.

According to an example embodiment of the invention, the DC+ area of the of the first outer conducting layer and the DC+ area of the second outer conducting layer are arranged opposite to each other with respect to the multi-layer circuit board. Analogously, the AC area of the first outer conducting layer and the AC area of the second outer conducting layer are arranged opposite to each other with respect to the multi-layer circuit board. Analogously, the DC− area of the first outer conducting layer and the DC− area of the second outer conducting layer are arranged opposite to each other with respect to the multi-layer circuit board. With respect to a view direction onto the plane of the multi-layer circuit board, the DC+ areas, AC areas and/or DC− areas may overlap each other substantially completely.

According to an example embodiment of the invention, from a view direction onto the power semiconductor module, the intermediate conducting layer overlaps at least eighty percent (80%) of the DC+ area, the AC area, and the DC− area of the first outer conducting layer and/or the second outer conducting layer. It also may be that the intermediate conducting layer overlaps the DC+ area, the AC area, and the DC− area of the first outer conducting layer and/or the second outer conducting layer completely.

According to an example embodiment of the invention, the first semiconductor chip and the second semiconductor chip are arranged in a row along the DC+ area, the AC area and the DC− area of the first outer conducting layer. Analogously, the third semiconductor chip and the fourth semiconductor chip are arranged in a row along the DC+ area, the AC area and the DC− area of the second outer conducting layer.

According to an example embodiment of the invention, gate driver components are arranged on and/or bonded to the first outer conducting layer and/or the second outer conducting layer. These gate driver components may be supplied with gate signals for the upper and/or lower half of the half-bridge formed by the power semiconductor module. The gate driver components, which may include an integrated circuit and/or passive components, such as resistors, capacitors, etc., convert the gate signal to signals supplied to the control electrodes of the semiconductor chips.

According to an example embodiment of the invention, the gate driver components are arranged opposite to an AC terminal connected to the AC area of the first outer conducting layer and to the AC area of the second outer conducting layer. The gate driver components may be arranged besides the rows formed by the semiconductor chips.

According to an example embodiment of the invention, a first cooling element is bonded to a backside of the first semiconductor chip and the second semiconductor chip opposite to the multi-layer circuit board. Analogously, a second cooling element is bonded to a backside of the third semiconductor chip and the fourth semiconductor chip opposite to the multi-layer circuit board. Since pairs of two power semiconductor chips are arranged on opposite sides of the power semiconductor module, the pairs of two power semiconductor chips are altogether better reachable for cooling elements.

The backside of a semiconductor chip may be located opposite to a power electrodes side with the power electrodes of the semiconductor chip. As already mentioned, the semiconductor chip may have all electrodes of the semiconductor chip on a first side, i.e. the power electrodes side. The second side or backside may be cooled with the respective cooling element. Such cooling elements may have radiators (heat sinks) and/or may be water cooled and/or air cooled.

According to an example embodiment of the invention, each of the first cooling element and the second cooling element is made of a further substrate including two electrically conducting layers and an electrically isolating layer in between. The further substrate may be made of the same materials as the multi-layer circuit board, such as described above. The further substrate may be a DBC (direct bonded copper) substrate, an IMS (insulated metal substrate) or a PCB (printed circuit board).

According to an example embodiment of the invention, spacers are arranged between the multi-layer circuit board and the first cooling element and the second cooling element. The spacers may be used for mechanically supporting the first cooling element and the second cooling element on the multi-layer circuit board. The spacers also may be used for thermally connecting the first cooling element and the second cooling element to the multi-layer circuit board. Such spacers may be made of an electrically insulating material and/or thermally conducting material. The spacers may be used for directly cooling the DC+ area, the AC area, and/or the DC− areas provided on the multi-layer circuit board. In such a way, it may be avoided that these areas, which are directly connected to the power electrode side of the semiconductor chips, become too hot.

According to an example embodiment of the invention, the first semiconductor chip, the second semiconductor chip, the third semiconductor chip, and the fourth semiconductor chip are based on a wide bandgap semiconductor, for example GaN (gallium nitride) or SiC (silicon carbide). The die of each semiconductor chip may be made of a wide bandgap material. Such semiconductor chips allow for higher switching frequencies and/or higher operation voltages, e.g., relative to Si semiconductors.

These and other example aspects of the invention will be apparent from and elucidated with reference to the embodiments described hereinafter.

### BRIEF DESCRIPTION OF THE DRAWINGS

Below, example embodiments of the present invention are described in more detail with reference to the attached drawings.

FIG. 1 shows a circuit diagram of a power semiconductor module according to an example embodiment of the invention.

FIG. 2 shows a schematic cross-sectional view of a power semiconductor module according to an example embodiment of the invention.

FIG. 3 shows a schematic top view onto a power semiconductor module according to an example embodiment of the invention.

The reference symbols used in the drawings, and their meanings, are listed in summary form in the list of reference symbols below. In principle, identical parts are provided with the same reference symbols in the figures.

### DETAILED DESCRIPTION

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

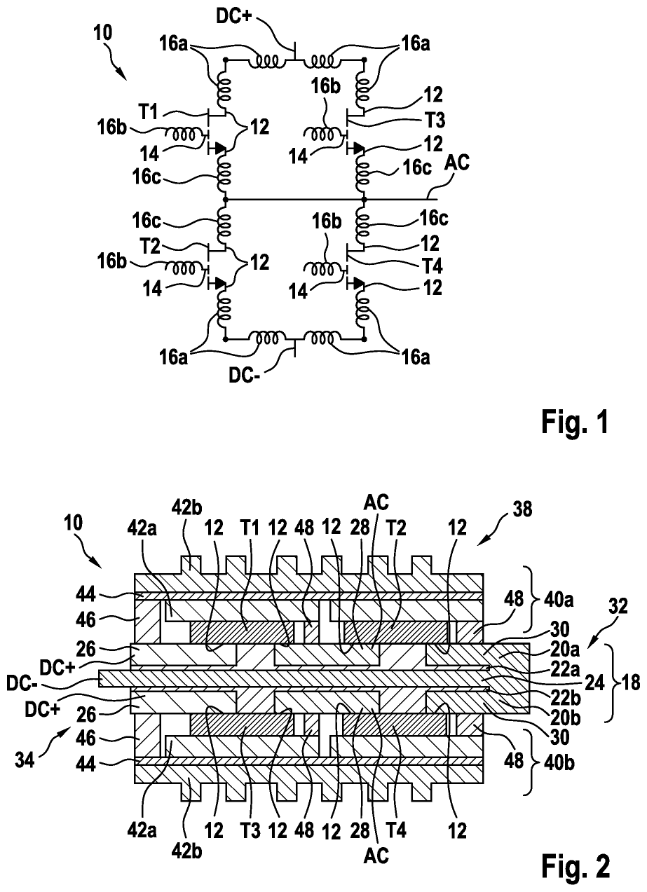

FIG. 1 shows a circuit diagram of a power semiconductor module 10, which is composed of four power semiconductor chips T1, T2, T3 and T4, which may be GaN or SiC transistors. Such wide bandgap semiconductor chips T1, T2, T3, T4 provide the possibility to operate the power semiconductor module 10 with higher voltages and/or higher switching frequencies, e.g., relative to Si semiconductors.

The semiconductor chips T1, T2 are connected in series to form a first half-bridge and the semiconductor chips T3, T4 are connected in series to form a second half-bridge. The two half-bridges are connected in series at a DC+ terminal, a DC− terminal, and an AC terminal. Each of the power semiconductor chips T1, T2, T3, T4 has two power electrodes 12 and a control electrode 14. The series connection of the power semiconductor chips T1, T2, T3, T4 is via the power electrodes 12.

FIG. 1 furthermore shows stray and/or parasitic inductances 16a, 16b, 16c, which can be reduced with the design such as shown in FIG. 2.

FIG. 2 shows a power semiconductor module 10 with a circuit diagram such as shown in FIG. 1. Same parts in FIG. 1 and FIG. 2 are depicted with the same reference numerals.

The power semiconductor module 10 includes a multi-layer circuit board 18, which in this order includes a first outer conducting layer 20a, a first isolating layer 22a, an intermediate conducting layer 24, a second isolating layer 22b and a second outer conducting layer 20b. The multi-layer circuit board 18 may be provided by a printed circuit board or by a DBC (direct bonded copper) substrate. The conducting layers 20a, 20b, 24 may be metallization layers, such as copper layers. Isolating layers 22a, 22b may be made of plastics or ceramics. It also may be that the multi-layer circuit board 18 includes more than five (5) layers.

The multi-layer circuit board 18 defines a plane, to which all the layers of the multi-layer circuit board 18 and also the layers of the cooling elements mentioned below run in parallel. This plane may be seen as main extension plane of the power semiconductor module 10.

The first outer conducting layer 20a and the second outer conducting layer 20b are structured to provide a DC+ area 26, an AC area 28 and a DC− area 30, which are separated from one another on the respective isolating layer 22a, 22b. The areas 26, 28, 30 may be seen as conductor paths and/or tracks, which provide a part of the electric circuitry of the power semiconductor module 10, such as shown in FIG. 1.

The semiconductor chip T1 is bonded with an electrode side to the DC+ area 26 and the AC area 28 of the conducting layer 20a, in particular such that one power electrode 12 is bonded to the DC+ area 26 and that the other one power electrode 12 is bonded to the AC area 28. The semiconductor chip T2 is bonded with an electrode side to the AC area 28 and the DC− area 30 of the conducting layer 20a, in particular such that one power electrode 12 is bonded to the AC area 28 and that the other one power electrode 12 is bonded to the DC− area 30.

The semiconductor chip T3 is bonded with an electrode side to the DC+ area 26 and the AC area 28 of the conducting layer 20b, in particular such that one power electrode 12 is bonded to the DC+ area 26 and that the other one power electrode 12 is bonded to the AC area 28. The semiconductor chip T4 is bonded with an electrode side to the AC area 28 and the DC− area 30 of the conducting layer 20b, in particular such that one power electrode 12 is bonded to the AC area 28 and that the other one power electrode 12 is bonded to the DC− area 30. As mentioned above, such power electrodes 12 may include drain, source, emitter, and collector electrodes.

Each of the semiconductor chips T1, T2, T3, T4 has a substantial cuboid body with a height substantially (such as at least five (5) times) smaller than a width and a length. The cuboid bodies may be oriented in parallel to the plane defined by the multi-layer circuit board 18. On one side, which may be seen as the front side, the power electrodes 12 are arranged. The opposite side may be seen as the backside of the respective semiconductor chip T1, T2, T3, T4.

The first semiconductor chip T1 and the second semiconductor chip T2 are arranged in a row along the DC+ area 26, the AC area 28 and the DC− area 30 of the first outer conducting layer 20a. The third semiconductor chip T3 and the fourth semiconductor chip T4 are arranged in a row along the DC+ area 26, the AC area 28 and the DC− area 30 of the second outer conducting layer 20b. The semiconductor chips T1 and T2 are electrically connected via the areas 26, 28, 30 into a first half-bridge and the semiconductor chips T3 and T4 are electrically connected via the areas 26, 28, 30 into a second half-bridge.

The DC− area 30 of the first outer conducting layer 20a and the DC− area 30 of the second outer conducting layer 20b are connected to the intermediate conducting layer 24 on a small side 32 of the multi-layer circuit board 18. This may be done with vias through the isolation layers 22a, 22b and/or with a conducting plate bonded to the small side 32 and/or to the DC− areas 30.

Small sides of the multi-layer circuit board 18 may be defined as the sides of the multi-layer circuit board 18, which run substantially orthogonal to the plane defined by the multi-layer circuit board 18. There are further small sides 34, 36, 38, which from the point of view in FIG. 2 are left, in front and behind the multi-layer circuit board 18.

The first semiconductor chip T1 and the third semiconductor chip T3 are arranged opposite to each other with respect to the multi-layer circuit board 18. Also, the second semiconductor chip T2 and the fourth semiconductor T4 chip are arranged opposite to each other with respect to the multi-layer circuit board 18. With respect to a view direction onto the multi-layer circuit board 18 and/or onto the plane defined by the multi-layer circuit board 18, the chips T1 and T2 as well as the chips T3 and T4 substantially overlap each other.

The same applies to the areas 26, 28, 30: The DC+ area 26 of the first outer conducting layer 20a and the DC+ area 26 of the second outer conducting layer 20b are arranged opposite to each other with respect to the multi-layer circuit board 18. The AC area 28 of the first outer conducting layer 20a and the AC area 28 of the second outer conducting layer 20b are arranged opposite to each other with respect to the multi-layer circuit board 18. The DC− area 30 of the first outer conducting layer 20a and the DC− area 30 of the second outer conducting layer 20b are arranged opposite to each other with respect to the multi-layer circuit board 18. With respect to a view direction onto the multi-layer circuit board 18 and/or onto the plane defined by the multi-layer circuit board 18, the areas 26, 28, 30 oppositely to each other substantially overlap each other.

From a view direction onto the multi-layer circuit board 18 and/or onto the plane defined by the multi-layer circuit board 18, the intermediate conducting layer overlaps nearly completely the DC+ area 26, the AC area 28 and the DC− area 30 of the first outer conducting layer 20a and/or the second outer conducting layer 20b.

The semiconductor module 10 further includes cooling elements 40a, 40b, which are arranged oppositely to each other with respect to the multi-layer circuit board 18. The first cooling element 40a is bonded or otherwise attached to backsides of the semiconductor chips T1 and T2. The second cooling element 40b is bonded or otherwise attached to backsides of the semiconductor chips T3 and T4.

The cooling elements 40a, 40b may be any kind of cooling element and/or may be based on air and water cooling. Also, active and passive cooling may be possible. As shown in FIG. 2, each of the cooling elements 40a, 40b may be made of a substrate including two (electrically) conducting layers 42a, 42b and an (electrically) isolating layer 44 in between. The conducting layer 42b may be provided with cooling fins.

For increasing the mechanical stability and improving the cooling performance of the power semiconductor module 10, spacers 46, 48 are provided, which are arranged between the multi-layer circuit board 18 and the cooling elements 40a, 40b. Each of the spacers 46, 48 may be a post or bar, which is in contact with the multi-layer circuit board 18 and one of the cooling elements 40a, 40b. The spacers 46, 48 may be made of an electrically isolating material with good thermal conducting properties. For example, the heat conducting coefficient of the spacers 46, 48 may be higher than the one of the semiconductor chips T1, T2, T3, T4.

As an example, the spacers 46 are directly attached to the isolating layer 44 of the cooling elements 40a, 40b and are bonded or otherwise attached to the DC+ areas 26. In such a way, the DC+ areas 26 and the DC+ terminal and/or a busbar attached thereto may be cooled efficiently.

As a further example, the spacers 48 are bonded or otherwise attached to the outer conducting layers 20a, 20b of the multi-layer circuit board 18 and to the electrically conducting layer 42a of the cooling elements 40a, 40b.

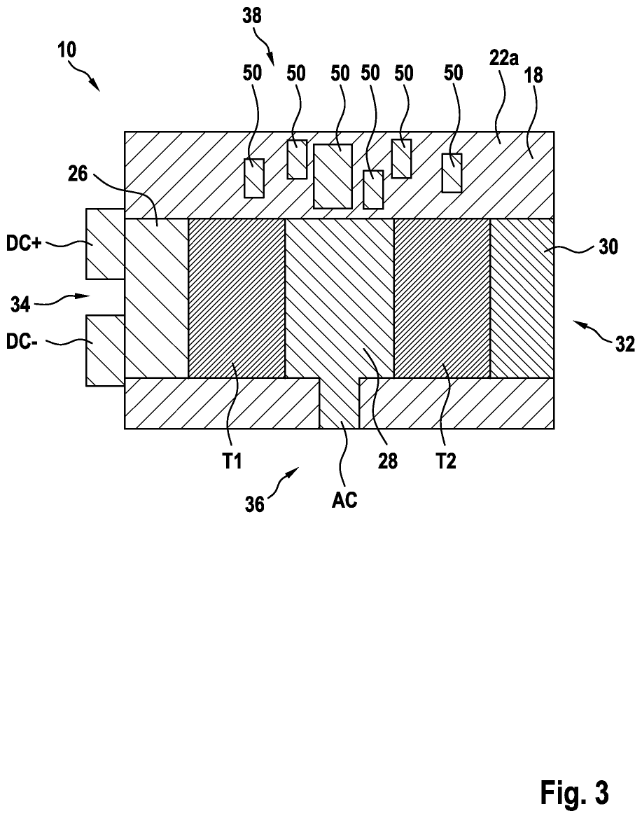

FIG. 3 shows a cross-sectional view of the power semiconductor module 10 in a view direction onto the multi-layer circuit board 18. It can be seen that a DC− terminal is provided, which is connected to intermediate conducting layer 24 (see also FIG. 2). The DC− terminal may be provided by a part of the intermediate conducting layer 24, which part protrudes from the multi-layer circuit board 18. It also is possible that the DC− terminal is a conducting plate or post bonded to the intermediate conducting layer 24. The DC− terminal is provided at a small side 34 located opposite to the small side 32.

A DC+ terminal is connected to the DC+ area 26 of the first outer conducting layer 20a and to the DC+ area 26 of the second outer conducting layer 20b. The DC+ terminal may be provided by a part of the conducting layers 20a, 20b, which parts protrudes from the multi-layer circuit board 18. It also is possible that the DC+ terminal is a conducting plate or post bonded to the conducting layers 20a, 20b. The DC+ terminal is provided at the small side 34.

The DC+ terminal and the DC− terminal are arranged at the same side 34 of the power semiconductor module 10.

An AC terminal is connected to the AC areas 28 of the first outer conducting layer 20a and the second outer conducting layer 20b. Both AC areas 28 are interconnected with each other, for example with vias through the isolation layers 22a, 22b, at a position where the intermediate layer 24 is not present. It also may be that the AC areas 28 are connected with a plate or post bonded to a small side 36 of the multi-layer circuit board 18.

The AC terminal is arranged at the small side 36 of the multi-layer circuit board 18, which runs orthogonal to the side, where the DC+ terminal and the DC− terminal are arranged.

Due to the design as shown in FIG. 2 with the DC− terminal between and close to the DC+ areas 26 and the DC− areas 30, the stray inductances 16a for the power loops are reduced. Also, the stray inductances 16c for the AC side are reduced in this way.

Furthermore, the symmetric layout for the paralleled power semiconductor chips T1, T2, T3 and T4 results in a good current balance. The power loop inductance for the power semiconductor chips T1,T3 is nearly the same as for the power semiconductor chips T2,T4.

FIG. 3 furthermore shows gate driver components 50, which are arranged on and/or bonded to the first outer conducting layer 20a. Also, such gate driver components 50 may be arranged on and/or bonded to the second outer conducting layer 20b. The gate driver components 50 may include an integrated circuit and/or passive components, such as resistors, capacitors, etc.

The gate driver components 50 are arranged opposite to the AC terminal at the small side 38.

As the gate driver components 50 are arranged close to the power semiconductor chips T1, T2, T3 and T4, the stray inductances 16b for the gate driver circuit and the connections of the gate driver circuit to the control electrodes 14 are reduced.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art and practicing the claimed invention, from a study of the drawings, the disclosure, and the appended claims. In the claims, the word “comprising” does not exclude other elements or steps, and the indefinite article “a” or “an” does not exclude a plurality. A single processor or controller or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

### LIST OF REFERENCE SYMBOLS

10 power semiconductor module
T1 first semiconductor chip
T2 second semiconductor chip
T3 third semiconductor chip
T4 fourth semiconductor chip
DC+ DC+ terminal
DC− DC− terminal
AC AC terminal
12 power electrode
14 control electrode
16a stray inductance
16b stray inductance
16c stray inductance
18 multi-layer circuit board
20a first outer conducting layer
20b second outer conducting layer
22a first isolating layer
22b second isolating layer
24 intermediate conducting layer
26 DC+ area
28 AC area
30 DC− area
32 first small side
34 second small side
36 third small side
38 fourth small side
40a first cooling element
40b second cooling element
42a first conducting layer
42b second conducting layer
44 isolating layer
46 spacer
48 spacer
50 gate driver component

1-13: (canceled)

14. A power semiconductor module (10), comprising:
a multilayer circuit board (18) comprising a first outer conducting layer (20a), a first isolating layer (22a), an intermediate conducting layer (24), a second isolation layer (22b), and a second outer conducting layer (20b) that are arranged in order;
a first semiconductor chip (T1) and a second semiconductor chip (T2) that are bonded to the first outer conducting layer (20a); and
a third semiconductor chip (T3) and a fourth semiconductor chip (T4) that are bonded to the second outer conducting layer (20b);
wherein the first outer conducting layer (20a) is arranged into a DC+ area (26), an AC area (28), and a DC− area (30), which are separated on the first isolating layer (20a) and interconnect the first semiconductor chip (T1) and the second semiconductor chip (T2) into a first half-bridge,
wherein the second outer conducting layer (20b) is arranged into a DC+ area (26), an AC area (28), and a DC− area (30), which are separated on the second isolating layer (20b) and interconnect the third semiconductor chip (T3) and the fourth semiconductor chip (T4) into a second half-bridge,
wherein the DC− area (30) of the first outer conducting layer (20a) and the DC− area (30) of the second outer conducting layer (20b) are connected to the intermediate conducting layer (24),
wherein a DC+ terminal (DC+) is connected to the DC+ area (26) of the first outer conducting layer (20a) and to the DC+ area (26) of the second outer conducting layer (20b),
wherein an AC terminal (AC) is connected to the AC area (28) of the first outer conducting layer (20a) and to the AC area (28) of the second outer conducting layer (20b), and
wherein a DC− terminal (DC−) is connected to intermediate conducting layer (24).

15. The power semiconductor module (10) of claim 14, wherein the DC+ terminal (DC+) and the DC− terminal (DC−) are arranged at a first side of the power semiconductor module (10).

16. The power semiconductor module (10) of claim 15, wherein the DC− area (30) of the first outer conducting layer (20a) and the DC− area (30) of the second outer conducting layer (20b) are connected to the intermediate conducting layer (24) at a second, opposite side of the power semiconductor module (10).

17. The power semiconductor module (10) of claim 15, wherein the AC terminal (AC) is arranged at a third side of the power semiconductor module (10) that is oriented orthogonal to the first side.

18. The power semiconductor module (10) of claim 14, wherein:
the first semiconductor chip (T1) is disposed opposite the third semiconductor chip (T3) about the multi-layer circuit board (18); and
the second semiconductor chip (T2) is disposed opposite the fourth semiconductor chip (T4) about the multi-layer circuit board (18).

19. The power semiconductor module (10) of claim 14, wherein:
the DC+ area (26) of the first outer conducting layer (20a) is disposed opposite the DC+ area (26) of the second outer conducting layer (20b) about the multi-layer circuit board (18);
the AC area (28) of the first outer conducting layer (20a) is disposed opposite the AC area (28) of the second outer conducting layer (20b) about the multi-layer circuit board (18); and
the DC− area (30) of the first outer conducting layer (20a) is disposed opposite the DC− area (30) of the second outer conducting layer (20b) about the multi-layer circuit board (18).

20. The power semiconductor module (10) of claim 19, further comprising spacers (46, 48) arranged between the multi-layer circuit board (18) and the first cooling element (40a) and the second cooling element (40b) for mechanically supporting the first cooling element (40a) and the second cooling element (40b) on the multi-layer circuit board (18) and/or for thermally connecting the first cooling element (40a) and the second cooling element (40b) to the multi-layer circuit board (18).

21. The power semiconductor module (10) of claim 14, wherein, from a view direction onto the power semiconductor module (10), the intermediate conducting layer overlaps no less than eighty percent of the DC+ area (26), the AC area (28), and the DC− area (30) of the first outer conducting layer (20a).

22. The power semiconductor module (10) of claim 21, further comprising spacers (46, 48) arranged between the multi-layer circuit board (18) and the first cooling element (40a) and the second cooling element (40b) for mechanically supporting the first cooling element (40a) and the second cooling element (40b) on the multi-layer circuit board (18) and/or for thermally connecting the first cooling element (40a) and the second cooling element (40b) to the multi-layer circuit board (18).

23. The power semiconductor module (10) of claim 14, wherein, from a view direction onto the power semiconductor module (10), the intermediate conducting layer overlaps no less than eighty percent of the DC+ area (26), the AC area (28), and the DC− area (30) of the second outer conducting layer (20b).

24. The power semiconductor module (10) of claim 14, wherein:
the first semiconductor chip (T1) and the second semiconductor chip (T2) are arranged in a row along the DC+ area (26), the AC area (28), and the DC− area (30) of the first outer conducting layer (20a); and
the third semiconductor chip (T3) and the fourth semiconductor chip (T4) are arranged in a row along the DC+ area (26), the AC area (28), and the DC− area (30) of the second outer conducting layer (20b).

25. The power semiconductor module (10) of claim 14, wherein:
gate driver components (50) are arranged on and/or bonded to one or both of the first outer conducting layer (20a) and the second outer conducting layer (20b); and
the gate driver components (50) are arranged opposite to the AC terminal (AC).

26. The power semiconductor module (10) of claim 14, further comprising:
a first cooling element (40a) attached to a backside of the first semiconductor chip (T1) and the second semiconductor chip (T2) opposite to the multi-layer circuit board (18); and
a second cooling element (40b) attached to a backside of the third semiconductor chip (T3) and the fourth semiconductor chip (T4) opposite to the multi-layer circuit board (18).

27. The power semiconductor module (10) of claim 26, wherein each of the first cooling element (40a) and the second cooling element (40b) comprises a substrate with two electrically conducting layers (42a, 42b) and an electrically isolating layer (44) between the two electrically conducting layers (42a, 42b).

28. The power semiconductor module (10) of claim 14, wherein the first semiconductor chip (T1), the second semiconductor chip (T2), the third semiconductor chip (T3), and the fourth semiconductor chip (T4) comprise a wide bandgap semiconductor material.
